(19) United States
(12) Patent Application Publication
(10) Pub. No.: US 2010/0052721 A1
(43) Pub. Date: Mar. 4, 2010

(54) TEST SOCKET AND TEST MODULE

(76) Inventor: Chiu-Fang Chang, Hsin-chu (TW)

Correspondence Address: STOUT, UXA, BUYAN & MULLINS LLP, 4 VENTURE, SUITE 300, IRVINE, CA, 92618, US

(21) Appl. No.: 12/253,872

(22) Filed: Oct. 17, 2008

(30) Foreign Application Priority Data
Aug. 28, 2008 (TW) 097132854

(51) Int. Cl. G01R 31/28

(52) U.S. Cl. 324/761

(57) ABSTRACT

The present invention discloses a test socket for testing an image sensor that comprises a sensing area facing a light source. The test socket comprises a signal-connecting mechanism for transmitting a signal between the image sensor and a source of the test signal, a bearing layer having an opening and being arranged at the surface facing the light source, and a transparent layer arranged between the image sensor and the bearing layer for supporting the image sensor.

### BACKGROUND OF THE INVENTION

1. Field of the Invention

The present invention relates to a test socket and a test module, and more particularly, to a test socket and a test module of an image sensor.

2. Description of the Prior Art

An image sensor such as a Complementary Metal-Oxide-Semiconductor (CMOS) or a Charge-Coupled Device (CCD) will proceed with a final test after the packaging is finished.

FIG. 1 shows a conventional test module for the final test of an image sensor. For testing an image sensor 18, the test module 1 comprises a light source 10, a test head 11, a plurality of pogo-pins 13, a pogo-tower 12, a signal board 16, a test board 15, a load board 14, and a test socket 17.

The light source 10 is arranged at an opening 19 of the test head 11; when testing, the light source 10 irradiates a smooth, uniform light 27 sequentially transmitted through an opening 20 of the load board 14, an opening 21 of the pogo-tower 12, an opening 22 of the test board 15, an opening 23 of a bearing layer 28 of the test socket 17, and reaches a sensing area 24 of the image sensor 18 finally.

The sensing area 24 comprises a pixel array (not shown), and the pixel array may be covered by a transparent window (not shown) for transmitting the light 27 to each of the pixels.

The test head 11 provides test signals. The load board 14 transmits the test signals through the pogo-tower 12, the test board 15, and the plurality of pogo-pins 13 to reach the signal board 16. The image sensor 18 comprises a plurality of pads 25 for electrically connecting a plurality of pins 26 of the test socket 17, which is electrically connected with the signal board 16, such that the test signals can be transmitted to the image sensor 18. When testing, the light source 10 radiates the light 27 to each pixel of the sensing area 24, each pixel senses the light, and test results are transmitted back to the test head 11 via a reverse path as mentioned above.

FIG. 2 is a partial view of FIG. 1 showing defects of the prior art. Ideally, the light 27 radiated from the light source 10 to the sensing area 24 is in a form of collimated light; actuality, the light 27 is radiated in a form of non-collimated light, as shown in FIG. 2. Although the bearing layer 28 of the test socket 17 is made of polymer having low refractive index, and sidewalls of the opening 23 of the bearing layer 28 and sidewalls of the opening 22 of the test board 15 may be coated with a film having low refractive index, whereby the non-collimated light 27 is transmitted into the sensing area 24 at an angle due to the reflection, and results in an uneven illumination or shadowing of the sensing area 24.

To lower reflections of the non-collimated light 27, the width of the opening 23 of the bearing layer 28 may be enlarged; however, with the size of the image sensor 18 getting smaller and smaller, the width of the opening 23 of the bearing layer 28 cannot be broadened so much as to lose the minimum amount of reinforcement required for supporting the image sensor 18. In addition, as a consequence of the size of the image sensor 18 being minimized, the distance between the sensing area 24 and the edge of the image sensor 18 is reduced as well. This will also contribute to the uneven illumination or shadowing of the sensing area.

Moreover, various test sockets 17 having different widths of the opening 23 of the bearing layer 28 are needed for different image sensor 18 having different sizes. This will waste time and increase cost.

Therefore, it would be advantageous to provide a test socket and test module that overcomes the defects of the prior art.

### SUMMARY OF THE INVENTION

An object of the present invention is to provide a novel test socket and a test module for preventing an uneven illumination or shadowing of the sensing area, as well as reducing cost and increasing efficiency.

According to the object, the present invention provides a test socket for testing an image sensor, the image sensor comprising a sensing area facing a light source, the test socket comprising: a signal-connecting mechanism, for transmitting test signals and test results between the image sensor and a signal source; a bearing layer, arranged in a surface facing the light source, the bearing layer having an opening for passing through a light radiated from the light source; and a transparent layer, pervious to the light to an extent, arranged between the bearing layer and the image sensor, the transparent layer bearing the image sensor.

According to the object, the present invention provides a test module for testing an image sensor, the image sensor comprising a sensing area facing a light source, the test module comprising a test socket that comprises a signal board and a plurality of pogo-pins electrically connected with each other; a bearing layer, arranged in a surface facing the light source, the bearing layer having an opening for passing through a light radiated from the light source; and a transparent layer, pervious to the light to an extent, arranged between the bearing layer and the image sensor, the transparent layer bearing the image sensor. The test module further comprises a test board having an opening, the test board being arranged below the plurality of pogo-pins and electrically connected with the test socket; a pogo-tower arranged below the test board and electrically connected with the test board; a load board arranged below the pogo-tower and electrically connected with the pogo-tower; a test head having an opening, the test head being arranged below the load board and electrically connected with the load board; and a light source arranged at the opening of the test head, the light source radiating a light through the opening of said bearing layer to the sensing area of the image sensor.

### BRIEF DESCRIPTION OF THE DRAWINGS

FIG. 1 is a side view of a conventional test module.

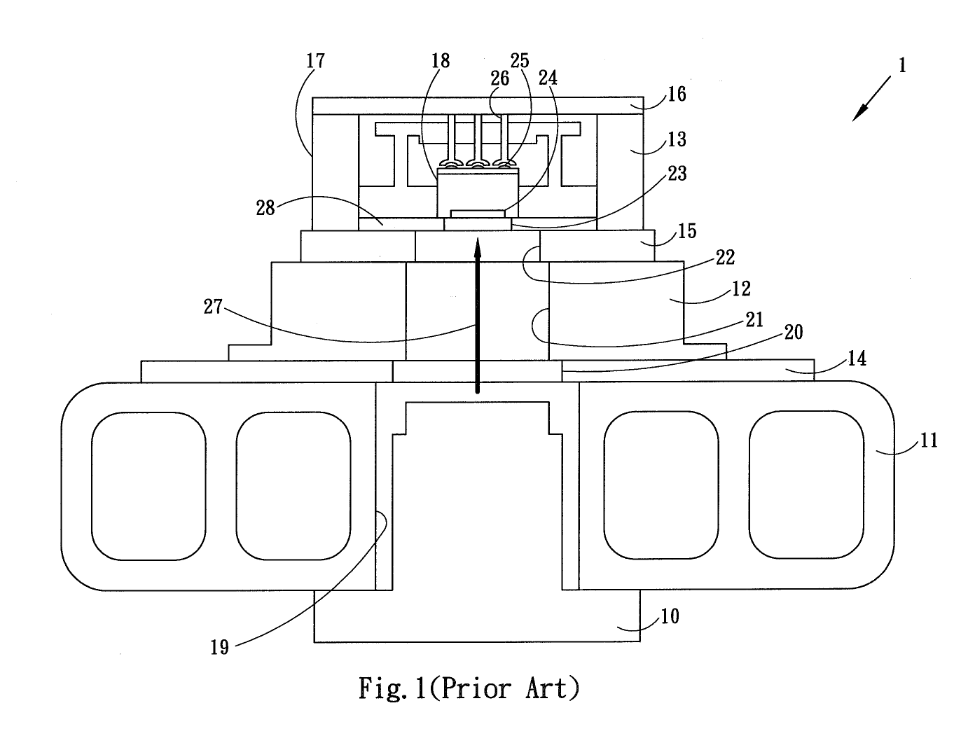

FIG. 2 is a partial view of FIG. 1 to show defects of the prior art.

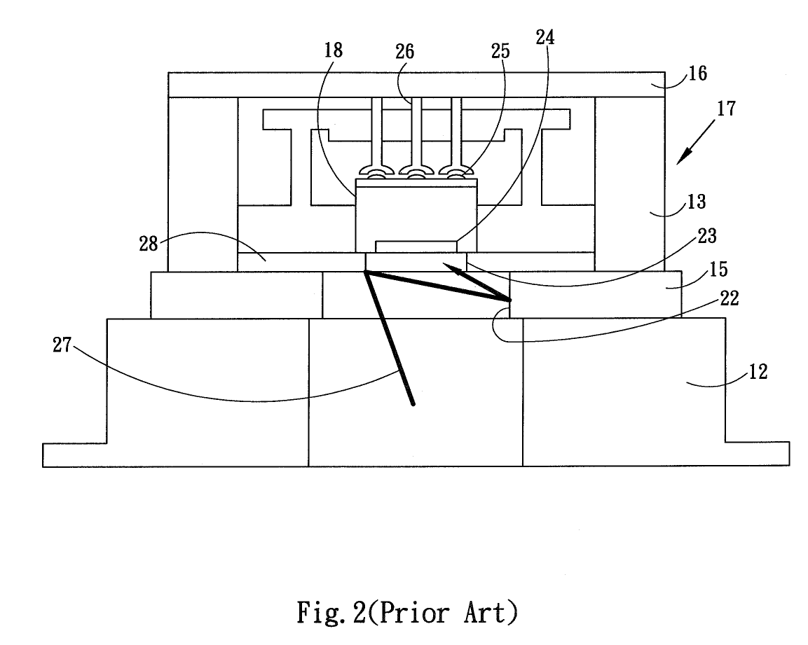

FIG. 3 is a side view of a test socket according to one embodiment of the present invention.

FIG. 4 is a side view of a test module according to one embodiment of the present invention.

### DESCRIPTION OF THE PREFERRED EMBODIMENT

The detailed description of the present invention will be discussed in the following embodiments, which are not intended to limit the scope of the present invention, but can be adapted for other applications. While drawings are illustrated in details, it is appreciated that the quantity of the disclosed components may be greater or less than that disclosed, except expressly restricting the amount of the components. Wherever possible, the same or similar reference numbers are used in drawings and the description to refer to the same or like parts. It should be noted that any drawings presented are in simplified form and are not to precise scale. In reference to the disclosure herein, for purposes of convenience and clarity only, directional terms, such as, top, bottom, left, right, up, down, over, above, below, beneath, rear, and front, are used with respect to the accompanying drawing. Such directional terms should not be construed to limit the scope of the invention in any manner.

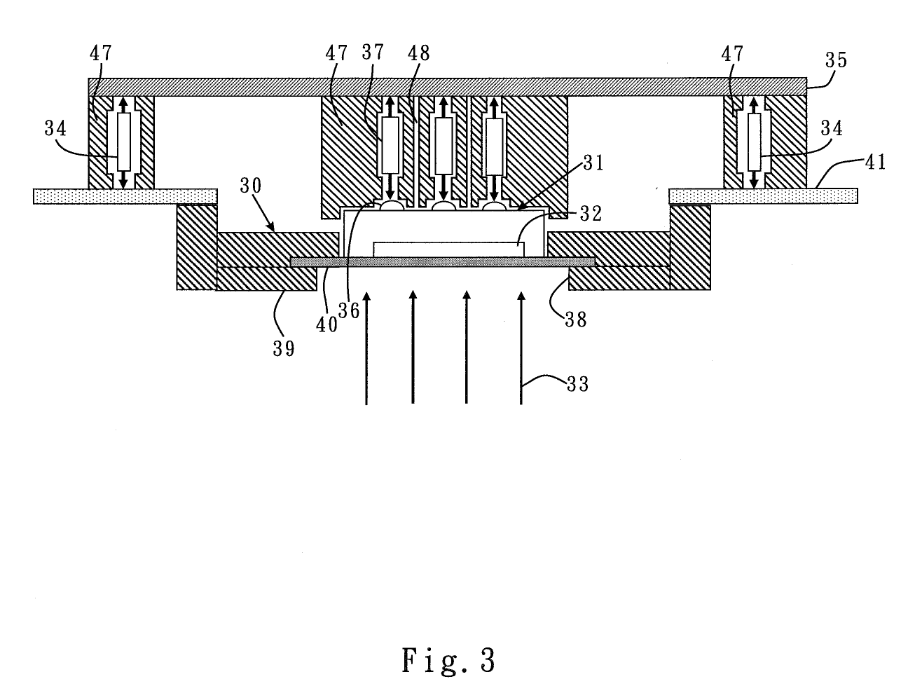

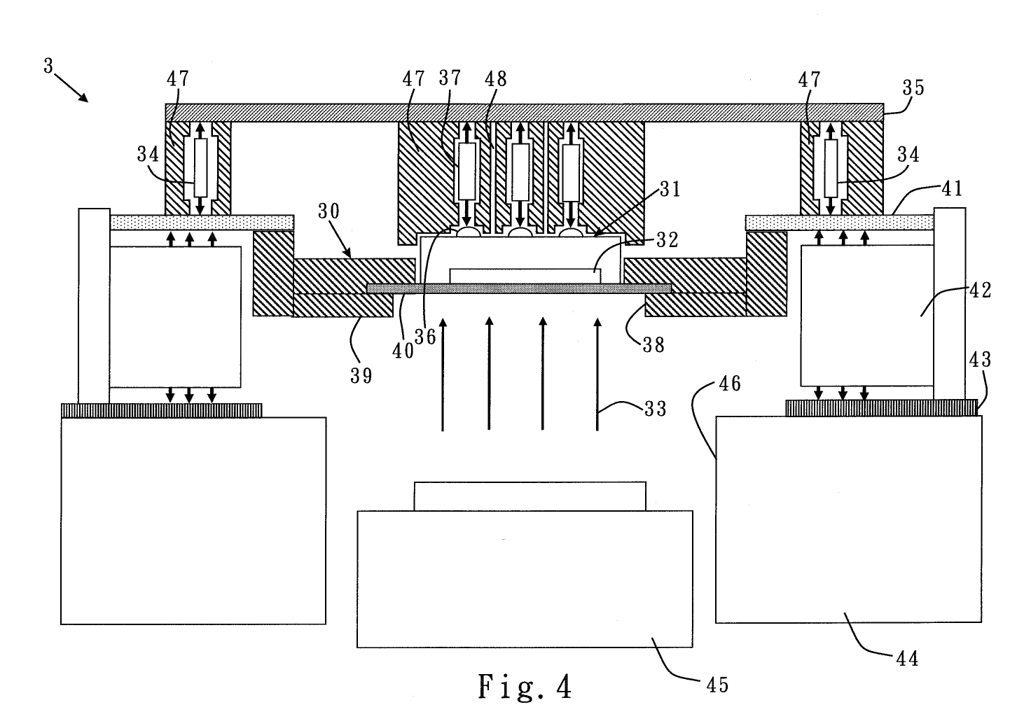

FIG. 3 shows a side view of a test socket 30 according to one embodiment of the present invention. The test socket 30 is employed for placing an image sensor 31, such as a Complementary Metal-Oxide-Semiconductor (CMOS) or a Charge-Coupled Device (CCD). The image sensor 31 comprises a sensing area 32 having a pixel array (not shown) to face a light source 45 (see FIG. 4). A transparent window (not shown) may cover the pixel array for transmitting a light 33 radiated from the light source 45 to each of the pixels.

In a surface opposite to the sensing area 32, the image sensor 31 comprises a plurality of pads 36 for electrically connecting a plurality of pins 37 of the test socket 30 respectively, where the plurality of pins 37 are arranged and vacuumed in a housing 47 and is electrically connected with a signal board 35. The test socket 30 further comprises a plurality of pogo-pins 34 arranged in the housing 47 as well. When testing, a signal source (not shown) provides test signals transmitted through the plurality of pogo-pins 34, the signal board 35, and the plurality of pins 37 to the image sensor 31.

Further, the test socket 30 comprises a bearing layer 39 in a surface facing the light 33. The bearing layer 39 has an opening 38, the width of the opening 38 larger than the width of the sensing area 32. The shape of the opening 38 is not limited and may consist with the shape of the sensing area 32. If the shape of the sensing area 32 is rectangular, the shape of the opening 38 may be rectangular, and the length and the width of the opening 38 are larger than the length and the width of the sensing area 32 respectively; if the shape of the sensing area 32 is circular, the shape of the opening 38 may be circular, and the circumference of the opening 38 is larger than the circumference of the sensing area 32.

Moreover, the test socket 30 further comprises a transparent layer 40 arranged between the bearing layer 39 and the image sensor 31. The transparent layer 40 is pervious to light to an extent and may be made from one of quartz, glass, tempered glass, polymer, optical material, and combination thereof. A diffuser may be one example of the optical material. The shape of the transparent layer 40 is not limited and may consist with the shape of the sensing area 32 or the opening 38 of the bearing layer 39. The size (or the circumference) of the transparent layer 40 is equal or larger than the size (or the circumference) of the opening 38. For example, if the shape of the opening 38 is rectangular, the shape of the transparent layer 40 may be rectangular, and the length and width of the transparent layer 40 are larger than the length and width of the opening 38 respectively; if the shape of the opening 38 is circular, the shape of the transparent layer 40 may be circular, and the circumference of the transparent layer 40 is larger than the circumference of the opening 38.

When testing, the light 33 is radiated through the opening 38 of the bearing layer 39 to each pixel of the sensing area 32, each pixel senses the light 33, and a test result is transmitted back to the signal source via a reverse path as mentioned above.

It is appreciated that there may be various signal-connecting mechanisms for various image sensors. According to the present invention, the signal-connecting mechanism as shown above is not limited in elements comprising the plurality of pads 36, the plurality of pins 37, the signal board 35, and the plurality of pogo-pins 34; it may comprise other elements or connects test signals in other forms. The key concept of the present invention is that the test socket 30 comprises: the bearing layer 39 facing the light, the dimension of an opening 38 of the bearing layer 39 larger than the dimension of the sensing area 32 of the image sensor 31, the transparent layer 40 arranged between the image sensor 31 and the bearing layer 39, and a signal-connecting mechanism for transmitting test signals and test results between the image sensor 31 and the signal source.

FIG. 4 shows a test module according to one embodiment of the present invention. A test module 3 comprises a test socket, of which the elements and variations are the same as the above embodiment. The test module 3 further comprises a test board 41 arranged below the plurality of pogo-pins 34, a pogo-tower 42 arranged below the test board 41, a load board 43 arranged below the pogo-tower 42, a test head 44 arranged below the load board 43, and a light source 45 arranged at an opening 46 of the test head 44. When testing, the light source 45 radiates the light 33 through the opening 38 of the bearing layer 38 to the sensing area 32 of the image sensor 31.

In addition, the test head 44 provides test signals transmitted through the load board 43, the pogo-tower 42, the test board 41, the plurality of pogo-pins 34, the signal board 35, and the plurality of pins 37, and transmitting to the image sensor 31 finally. When the light 33 is irradiated to each pixel of the sensing area 32, a test result is transmitted back to the test head 44 through a reverse path that has been mentioned above.

As the embodiments disclosed herein, because the opening 38 of the bearing layer 39 has a width, circumference, or dimension larger than that of the sensing area 32, the uneven illumination or shadowing of the sensing area 32 due to reflection or other factors can be prevented. In addition, when the transparent layer 40 is made of a proper material, for example quartz, the light 33 will be evenly transmitted to the sensing area 32. Moreover, when a diffuser is employed as the transparent layer 40, it can scatter the light 33 well. The transparent layer 40 too can function as a supporting structure of the image sensor 31 no matter the sizes of the image sensor 31, therefore canceling the need to replace the test socket 30 or the bearing layer 39, and thus save time and reduce cost.

Although specific embodiments have been illustrated and described, it will be appreciated by those skilled in the art that various modifications may be made without departing from the scope of the present invention, which is intended to be limited solely by the appended claims.

What is claimed is:

1. A test socket for testing an image sensor, the image sensor comprising a sensing area facing a light source, the test socket comprising:
a signal-connecting mechanism, for transmitting test signals and test results between the image sensor and a signal source;
a bearing layer, arranged in a surface facing the light source, said bearing layer having an opening for passing light radiated from the light source; and
a transparent layer, pervious to the light to an extent, arranged between said bearing layer and the image sensor, said transparent layer bearing the image sensor.

2. The test socket as recited in claim 1, wherein the dimension of the opening of said bearing layer is larger than the dimension of the sensing area, and the dimension of said transparent layer is equal to or larger than the dimension of the opening of said bearing layer.

3. The test socket as recited in claim 1, wherein said transparent layer is made of a material selected from a group consisting of quartz, glass, tempered glass, polymer, optical material, and combinations thereof.

4. The test socket as recited in claim 3, wherein the optical material comprises a diffuser.

5. The test socket as recited in claim 1, said signal-connecting mechanism comprising:
a plurality of pins, for electrically connected with a plurality of pads of the image sensor respectively;
a signal board, electrically connected to the plurality of pins; and
a plurality of pogo-pins, arranged below the signal board and electrically connected to the signal board.

6. The test socket as recited in claim 1, wherein the image sensor comprises a Complementary Metal-Oxide-Semiconductor (CMOS) or a Charge-Coupled Device (CCD).

7. A test module for testing an image sensor, the image sensor comprising a sensing area facing a light source, the test module comprising:
a test socket, comprising:
a signal-connecting mechanism comprising a signal board and a plurality of pogo-pins electrically connected with each other for transmitting test signals to the image sensor;
a bearing layer, arranged in a surface facing the light source, said bearing layer having an opening for passing light radiated from the light source; and
a transparent layer, pervious to the light to an extent, arranged between said bearing layer and the image sensor, said transparent layer bearing the image sensor;
a test board having an opening, said test board being arranged below the plurality of pogo-pins and electrically connected with said test socket;
a pogo-tower arranged below the test board and electrically connected with said test board;
a load board arranged below the pogo-tower and electrically connected with said pogo-tower;
a test head having an opening, said test head being arranged below the load board and electrically connected with said load board, said test head providing test signals transmitted through said load board, said pogo-tower, and said test board to said test socket and the image sensor; and
a light source arranged at the opening of said test head, the light source radiating the light through the opening of said bearing layer to the sensing area of the image sensor.

8. The test module as recited in claim 7, wherein the dimension of the opening of said bearing is larger than the dimension of the sensing area, and the dimension of said transparent layer is equal to or larger than the dimension of the opening of said bearing layer.

9. The test module as recited in claim 7, wherein said transparent layer is made of a material selected from a group consisting of quartz, glass, tempered glass, polymer, optical material, and combinations thereof.

10. The test module as recited in claim 7, wherein the optical material comprises a diffuser.

11. The test module as recited in claim 7, wherein said signal-connecting mechanism further comprises a plurality of pins for being electrically connected with a plurality of pads of the image sensor respectively and electrically connected with said signal board.

12. The test module as recited in claim 7, wherein the image sensor comprises a Complementary Metal-Oxide-Semiconductor (CMOS) or a Charge-Coupled Device (CCD).
